(19) United States
(12) Patent Application Publication
(10) Pub. No.: US 2003/0003760 A1
(43) Pub. Date: Jan. 2, 2003

(54) Photoresist coating method and apparatus

(76) Inventors: Sung-Il Kim, Seoul (KR); Sung-Hyun Park, Suwon (KR); Jae-Kwan Song, Suwon (KR); Dong-Ho Cha, Suwon (KR); Yoon-Keun Lee, Seoul (KR); Young-Ho Park, Ohsan-Shi (KR); Kyung-Suk An, Suwon (KR); Young-Su Oh, Suwon (KR)

Correspondence Address: VOLENTINE FRANCOS, P.L.L.C., Suite 150, 12200 Sunrise Valley Drive, Reston, VA, 20191, US

(21) Appl. No.: 10/158,153

(22) Filed: May 31, 2002

(30) Foreign Application Priority Data
Jun. 27, 2001 (KR) 2001-36931

(51) Int. Cl. H01L 21/461; H01L 21/302

(52) U.S. Cl. 438/734

(57) ABSTRACT

A method of coating a wafer with photoresist includes steps of injecting solvent on a wafer, subsequently applying photoresist onto the wafer, rotating the wafer at a constant speed, and directing a laminar flow of air towards the wafer as it is rotating. Since the solvent is injected onto the wafer prior to the photoresist, the surface tension and viscosity of the photoresist are lowered. The laminar airflow suppresses turbulence at the surface of the wafer, which turbulence is otherwise created by the act of rotating the wafer. To this end, a cylinder is raised to form a chamber over the wafer, and filtered air is blown into the cylindrical chamber. These measures make it is possible for the photoresist film to be formed with a uniform thickness.

### BACKGROUND OF THE INVENTION

1. Field of the Invention

The present invention relates to a spin-coating process in the fabricating of semiconductor devices. More particularly, the present invention relates to a spin-on-glass type of spinner and to a method of applying photoresist onto a wafer using the same.

2. Description of the Related Art

The fabricating of semiconductor devices includes forming a desired pattern on a wafer. To this end, a wafer is coated with a photoresist and a developer. The photoresist is exposed and developed, using the developer, so as to be patterned. The pattern of the photoresist can then be transferred to an underlying layer.

Although there are various apparatus for coating a wafer with photoresist, spin-coating apparatus are the most widely used. In spin-coating, a wafer is loaded on a spin chuck and photoresist is dropped or injected onto a surface of the wafer. The spin chuck is rotated whereby centrifugal force causes the photoresist to spread across the wafer surface.

However, the spreading of the photoresist under centrifugal force results in an uneven distribution of the photoresist as seen from the center of the wafer to the outer peripheral edge of the wafer. That is, the thickness of the photoresist coating is non-uniform. Because the centrifugal force is greater in larger wafers, the pronounced non-uniformity in the distribution of photoresist across large wafers creates serious problems for relatively large wafers. Moreover, the rotation of the spin chuck creates turbulence that increases the non-uniformity of the coating. The turbulence becomes quite high at high rotary speeds, resulting in a correspondingly high degree of non-uniformity in the thickness of the film coating the wafer.

Still further, in an attempt to overcome the problems mentioned above, a solvent is typically sprayed onto the photoresist after the photoresist has been applied onto the wafer. The solvent, however, evaporates before the photoresist arrives at the outer peripheral edge of the wafer. Therefore, the film of photoresist still exhibits non-uniformity in the thickness thereof, particularly near the outer peripheral edge of the wafer, i.e., from the point at which the solvent has evaporated on top of the photoresist.

### SUMMARY OF THE INVENTION

Therefore, it is an object of the present invention to provide a method of and apparatus for coating a wafer with a uniform thickness of material, i.e., photoresist or developer.

According to one aspect of the present invention, a photoresist coating method comprises the steps of injecting a solvent onto a wafer, subsequently applying the photoresist onto the wafer, rotating the wafer at a constant speed, and forming a uni-directional laminar flow and directing the flow towards the surface of the wafer while the wafer is being rotated. Applying the photoresist onto the solvent obviates the problems associated with the evaporation of the solvent before the photoresist reaches the peripheral edge of the wafer. Therefore, the solvent can more assuredly cause the photoresist to spread uniformly across the wafer surface due to centrifugal force. Directing air towards the surface of the wafer while the wafer is being rotated can suppress turbulence otherwise produced by the rotation of the wafer.

According to another aspect of the present invention, a coating apparatus comprises a chuck to which the wafer is mounted and fixed, means for rotating the chuck at a high speed, a catch basin surrounding the chuck, and means for creating an airflow that suppresses the turbulence otherwise produced by the rotating of the chuck. In particular, an air manifold is disposed above the chuck for spraying air towards the wafer. The air is filtered by an air filter, e.g. a ULPA filter. A cylinder defines a chamber through which air flowing from the air manifold is confined to flow as a unidirectional laminar flow.

### BRIEF DESCRIPTION OF THE DRAWINGS

FIG. 1 is a cross-sectional view of a photoresist coating apparatus according to the present invention.

FIG. 2 is a flowchart of a method of coating a wafer according to the present invention.

### DETAILED DESCRIPTION OF THE PREFERRED EMBODIMENTS

Because the uniformity in the thickness of a film of photoresist is critical to the forming of a circuit pattern on a wafer, the method of applying the photoresist to the wafer is essential to fabricating quality semiconductor devices. In general, the processing of a silicon wafer as a prelude to the forming of a circuit pattern thereon includes an oxidation process and a photoresist coating process. In the oxidation process, an oxide layer is formed on the wafer to protect a polished silicon surface of the wafer. In the photoresist coating process, liquid-phased photoresist is applied to the oxide layer, and then the wafer is rotated at a high speed to form a coating across the oxide layer. As mentioned above, the apparatus that are widely used for coating a wafer in this way with photoresist are collectively referred to as spin-coating apparatus.

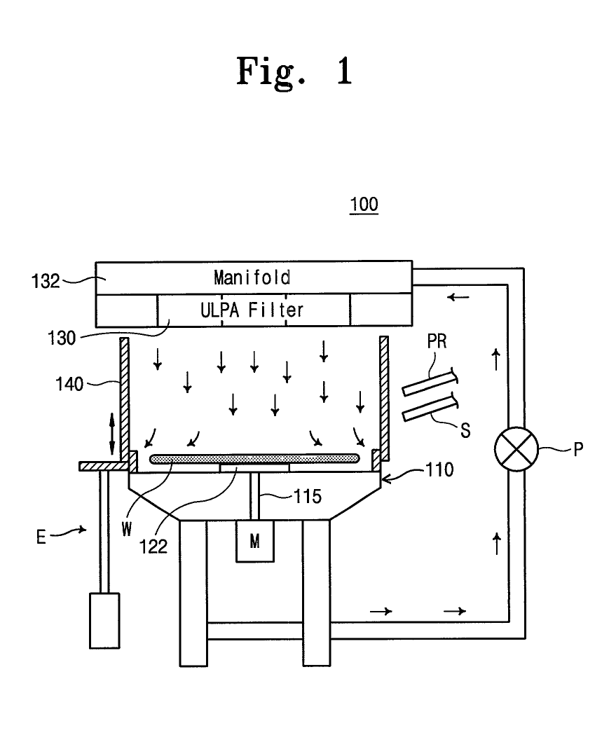

Referring now to FIG. 1, a wafer spin-coating apparatus 100 according to the present invention includes a catch basin 110, a rotary shaft 115, and a spin chuck 120. The catch basin 110 is continuously opened via an acrylic door (not shown) installed at the front of the catch basin 110. The rotary shaft 115 extends vertically in the center of the catch basin 110, and is rotated by a motor (or other appropriate rotary drive mechanism) M. The spin chuck 120 can affix a wafer W thereto. The spin chuck 120 is mounted to the rotary shaft 115 and is rotated in one direction by the motor M, whereby the wafer W is spun.

In the wafer coating apparatus, the wafer W is seated in a cassette. A main robot carries the wafer W from the cassette to a cooling plate. The wafer W is centered on the cooling plate by guide pins that are located at the periphery of the cooling plate. After the wafer W attains a certain temperature, lift pins raise the wafer W off of the cooling plate, and a shuttle moves the wafer W onto the spin chuck 120 in the catch basin 110. Photoresist is then applied to the wafer W via a photoresist nozzle PR, and the rotary shaft 115 and the spin chuck 120 are rotated by the motor M. In this way, the coating process is carried out. These aspects of spin-coating are conventional, per se, as is well known to those of ordinary skill in the art and thus, will not be described in further detail.

Referring again to FIG. 1, according to the spin-coating apparatus 100 of the present invention, an air manifold 132 is located over the catch basin 110 in which the spin chuck 120 is situated. A pump P pumps air to the manifold 132. A ULPA filter 130 is attached to the manifold 132 in such a way that the air forced through the manifold 132 is filtered by the ULPA filter. In addition, a transparent cylinder 140 is mounted to the catch basin 110 so as to be movable up and down relative thereto. An elevator E is connected to the cylinder 140 to raise and lower the cylinder 140 relative to the catch basin 110.

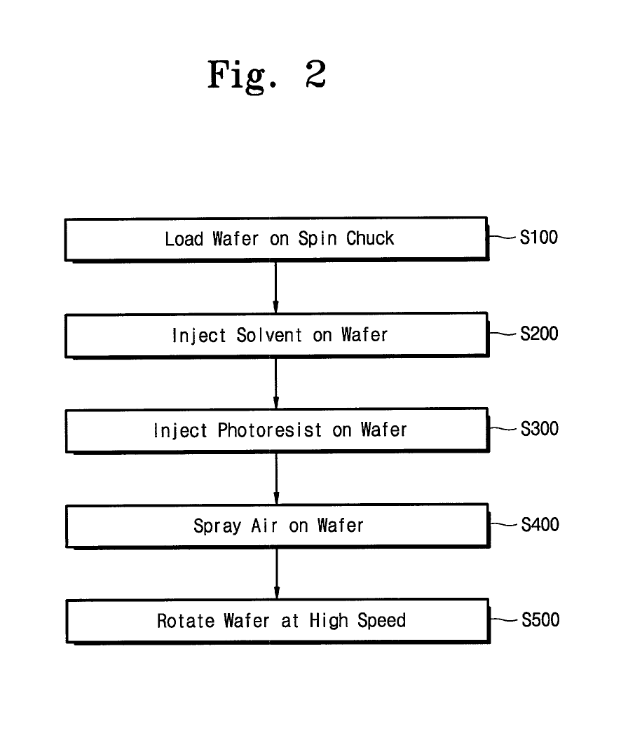

Referring now to FIG. 2, the method of the present invention will be described in detail. A wafer W is loaded on the spin chuck 120 (S100). Solvent is sprayed onto the wafer (S200) via a solvent applicator S (FIG. 1). Next, photoresist is applied on top of the solvent on the wafer (S300) using the photoresist applicator PR. The solvent lowers the surface tension and viscosity of the photoresist. Therefore, the photoresist can spread uniformly across the wafer. Next, the cylinder 140 is raised to surround the catch basin 110, whereupon air is sprayed (S400) through the manifold 132 towards the wafer. The air passes through the ULPA filter 130. The resultant airflow is confined by the cylinder 140, whereby the airflow is a unidirectional laminar flow all the way to the surface of the wafer. While exposed to this laminar airflow ambient, the wafer is rotated at a high speed (S500).

As described above, according to the present invention, solvent is injected onto a wafer surface prior to the application of photoresist. Hence, the surface tension and viscosity of the photoresist are lowered, whereby the photoresist flows smoothly to the outer peripheral edge of the wafer. Also, the air manifold and cylinder produce a laminar flow of air that impinges the surface of the wafer. As a result, the turbulence which would otherwise be created by the high speed rotation of the spin chuck is suppressed. Accordingly, a film of photoresist having a uniform thickness can be produced on the wafer.

Finally, although the present invention has been shown and described with respect to the preferred embodiments thereof, various changes in form and details, as will become apparent to those of ordinary skill in the art, may be made thereto without departing from the true spirit and scope of the invention as defined by the appended claims.

What is claimed is:

1. A method of forming a film of photoresist on a wafer, comprising:
injecting solvent on a surface of the wafer;
subsequently applying photoresist onto the solvent on the wafer; and
subsequently rotating the wafer at a constant speed.

2. The method of claim 1, and further comprising spraying air towards the surface of the wafer, as the wafer is being rotated.

3. The method of claim 2, and further comprising filtering the air before it reaches the wafer.

4. The method of claim 2, and further comprising confining the air to flow as a laminar airflow towards the surface of the wafer.

5. A method of forming a film on a wafer, comprising:
applying a film-forming material onto a surface on the wafer;
subsequently rotating the wafer at a constant speed to spread the film-forming material across the surface using centrifugal force; and
forming a unidirectional laminar flow and directing the flow towards the surface of the wafer while the wafer is being rotated to suppress turbulence produced by the rotating of the wafer.

6. An apparatus for coating a wafer, comprising:
a chuck to which the wafer can be affixed;
means for rotating said chuck;
a catch basin in which the chuck is situated;
an air manifold disposed above said chuck; and
a shroud interposed between said catch basin and said air manifold and defining a chamber through which air flowing from the air manifold is confined to flow as a unidirectional laminar flow towards the surface of a wafer affixed to the chuck.

7. The apparatus of claim 6, wherein said shroud is a cylinder extending vertically above said catch basin.

8. The apparatus of claim 7, wherein said cylinder is transparent.

9. The apparatus of claim 7, wherein said cylinder is mounted in the apparatus so as to be movable up and down.

10. The apparatus of claim 6, and further comprising an air filter positioned to filter air flowing from the air manifold.
